(19) United States
(12) Patent Application Publication
(10) Pub. No.: US 2010/0251075 A1
(43) Pub. Date: Sep. 30, 2010

(54) MEMORY CONTROLLER AND SEMICONDUCTOR MEMORY APPARATUS

(75) Inventors: Michiko TAKAHASHI, Kanagawa (JP); Kenji Sakaue, Kanagawa (JP); Hiroshi Sukegawa, Tokyo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/560,974

(22) Filed: Sep. 16, 2009

(30) Foreign Application Priority Data
Mar. 30, 2009 (JP) 2009-083051

(51) Int. Cl. H03M 13/05; G06F 11/10

(52) U.S. Cl. 714/773; 714/E11.034

(57) ABSTRACT

A memory controller that has an error correction number correspondence table that stores an error threshold level in correspondence with an error correction number; an error threshold level storage section that stores an error threshold level for each block; an uncorrected number measurement section that measures an uncorrected number of an error correction for each block; an error threshold level modification section that, each time an uncorrected number of a certain block exceeds a predetermined number, modifies the error threshold level of the block; an encoder that performs encoding processing of data stored in memory cells belonging to each block with an error correction number that is based on an error threshold level and the error correction number correspondence table; and a decoder that performs decoding processing of data.

### CROSS-REFERENCE TO RELATED APPLICATION

This application claims the benefit of Japanese Application No. 2009-83051 filed in Japan on Mar. 30, 2009, the contents of which are incorporated herein by this reference.

### BACKGROUND OF THE INVENTION

1. Field of the Invention

The present invention relates to a memory controller and a semiconductor memory apparatus that have an error correcting code section that performs encoding processing of data to generate encoded data and also performs decoding processing of encoded data. More particularly, the present invention relates to a memory controller and a semiconductor memory apparatus that can change an error correction number when performing encoding processing of data that is stored in a flash memory section.

2. Description of the Related Art

Japanese Patent Application Laid-Open Publication No. 2004-120419 discloses a Reed-Solomon encoding circuit that can arbitrarily set a frame length and an error correction number.

However, in a memory controller that performs encoding processing of data stored in a flash memory section to generate encoded data and also performs decoding processing of encoded data, a memory section that stores data is composed of a plurality of memory cells and probabilities of error occurring are not the same for data stored in the respective cells. Therefore, in a case in which the same error correction number is set uniformly for data stored in all memory cells, errors occur frequently when the error correction number that is set is small. In contrast, when the error correction number that is set is large, the error correcting code becomes long, that is, the length of encoded data is long because a parity is added to the data, and the capacity of a memory section in which the user can arbitrarily store data decreases. Further, processing times for encoding processing and decoding processing increase because unnecessary processing is performed. Thus, even when a memory controller that can simply increase or decrease an error correction number is used, it has not necessarily been easy to perform error correction processing efficiently.

### BRIEF SUMMARY OF THE INVENTION

According to one aspect of the present invention there is provided a memory controller that includes an error correction number correspondence table that stores an error threshold level in correspondence with an error correction number when performing encoding processing of data stored in the flash memory section, the error correction number capable of being increased or decreased, and the flash memory section being composed of a plurality of memory cells that are each classifiable into any one of a plurality of set units; an error threshold level storage section that stores an error threshold level for each of the set units; an uncorrected number measurement section that measures an uncorrected number of an error correction for each of the set units; an error threshold level modification section that, each time the uncorrected number of a certain set unit exceeds a predetermined number, modifies the error threshold level of the relevant set unit that is stored in the error threshold level storage section to a new error threshold level; an encoder that performs the encoding processing with the error correction number that is based on the error threshold level stored in the error threshold level storage section and the error correction number correspondence table; and a decoder that performs decoding processing of data that is stored in the flash memory section.

Further, according to another aspect of the present invention there is provided a semiconductor memory apparatus that includes a flash memory section composed of a plurality of memory cells that are each classifiable into any one of a plurality of set units; an error correction number correspondence table that stores an error threshold level in correspondence with an error correction number of a memory controller when performing encoding processing of data stored in the flash memory section, the error correction number capable of being increased or decreased; an error threshold level storage section that stores an error threshold level for each of the set units; an uncorrected number measurement section that measures an uncorrected number of an error correction for each of the set units; an error threshold level modification section that, each time the uncorrected number of a certain set unit exceeds a predetermined number, modifies the error threshold level of the relevant set unit that is stored in the error threshold level storage section to a new error threshold level; an encoder that performs the encoding processing with the error correction number that is based on the error threshold level stored in the error threshold level storage section and the error correction number correspondence table; and a decoder that performs decoding processing of data that is stored in the flash memory section.

### BRIEF DESCRIPTION OF THE DRAWINGS

FIG. 1 is a configuration diagram that illustrates the configuration of a semiconductor device according to a first embodiment;

FIG. 2 is a configuration diagram that illustrates the configuration of a semiconductor device according to the first embodiment;

FIG. 3 is a view that shows an example of an error correction number correspondence table of a memory controller according to the first embodiment;

FIG. 4 is a flowchart for describing decoding processing of the memory controller according to the first embodiment;

FIG. 5 is a configuration diagram for describing decoding processing of the memory controller according to the first embodiment;

FIG. 6 is a flowchart for describing encoding processing of the memory controller according to the first embodiment;

FIG. 7 is a configuration diagram for describing encoding processing of the memory controller according to the first embodiment; and

FIG. 8 is a configuration diagram that illustrates the configuration of a semiconductor device according to a second embodiment.

### DETAILED DESCRIPTION OF THE INVENTION

### First Embodiment

Hereunder, a memory controller and a semiconductor memory apparatus according to a first embodiment of the present invention are described with reference to the drawings.

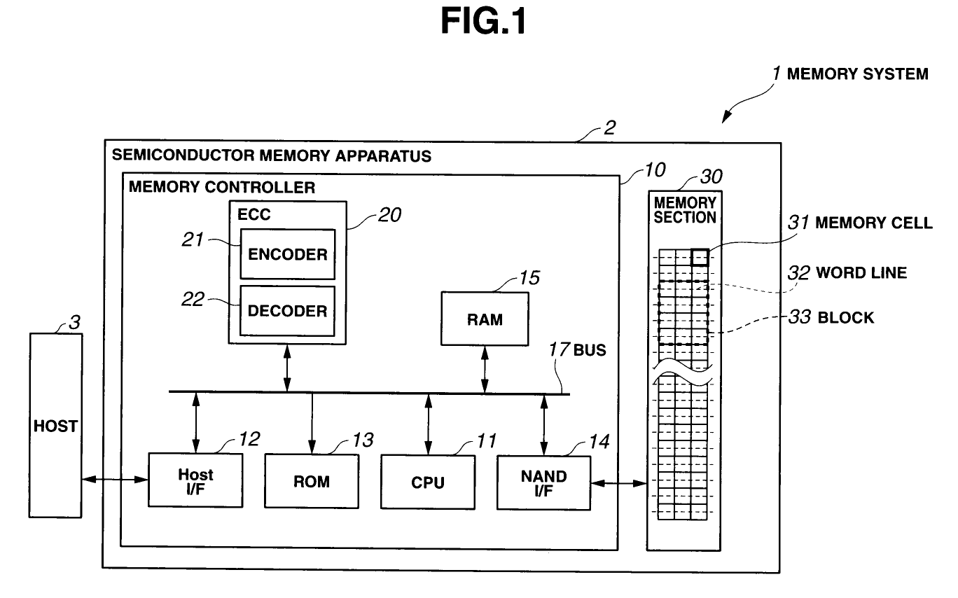

As shown in FIG. 1, a semiconductor memory apparatus 2 according to the present embodiment is a storage medium that is detachably connected to a host 3 such as a personal computer or a digital camera, and for example is in the form of a memory card. In this connection, a semiconductor memory apparatus (not shown) as an embodiment of the present invention may be a so-called embedded-type apparatus that is housed inside a host (unshown) and stores activation data and the like of the host, or a configuration such as a semiconductor disk: SSD (Solid State Drive) may also be adopted. Alternatively, the semiconductor memory apparatus 2 and the host 3 may be included in a memory system 1 such as an MP3 player that is a portable music player. The semiconductor memory apparatus 2 has a memory section 30 and a memory controller 10. The memory section 30 is a NAND-type flash memory section, and has a configuration in which a large number of memory cells 31 as unit cells are connected with a bit line (unshown) used for writing and a word line 32 used for reading and the like.

In this connection, the configuration of the semiconductor memory apparatus 2 that has the NAND-type flash memory section is simplified by erasing en bloc data that is stored in the plurality of memory cells 31. An erase unit when the data is subjected to en-bloc erase processing is a block 33 that is schematically illustrated in FIG. 1. In the semiconductor memory apparatus 2, a read unit of data stored in a plurality of memory cells 31 is a unit referred to as a “page” that is smaller in size than the block 33. More specifically, a page is composed of a plurality of the memory cells 31, the block 33 is composed of a plurality of pages, and the memory section 30 is composed of a plurality of the blocks 33.

The memory controller 10 includes a ROM 13; a CPU 11 that is a control section; a RAM 15; a host I/F (interface) 12; an error correcting code (ECC) section 20 that has an encoder 21 that performs encoding processing of data that is stored and outputs encoded data and a decoder 22 that performs decoding processing of encoded data that is stored, and that is capable of increasing or decreasing an error correction number; and a NAND I/F (interface) 14. These components of the memory controller 10 are connected through a bus 17. The memory controller 10 uses the CPU 11 to send and receive data to and from the host 3 via the host I/F 12, and to send and receive data to and from the memory section 30 via the NAND I/F 14.

As described in the foregoing, the memory controller 10 performs encoding processing and decoding processing of data stored in the memory section 30 in which a memory cell array including a plurality of memory cells 31 is composed of a plurality of blocks 33, and in which each block 33 is erasable in a block unit.

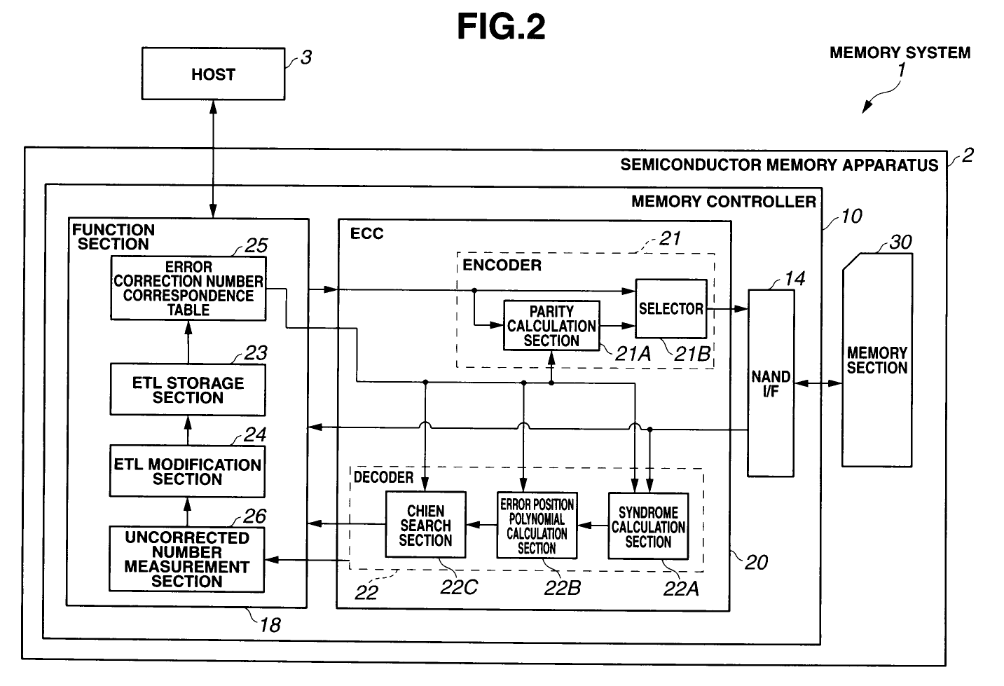

Next, the configuration of the memory controller 10 of the present embodiment is described in more detail using FIG. 2. As shown in FIG. 2, the memory controller 10 has an ECC 20 and a function section 18 with which the ECC 20 performs a function for increasing or decreasing an error correction number and the like.

The encoder 21 of the ECC 20 has a parity calculation section 21A that calculates a parity of a different parity length for each block 33 based on an error correction number that is stored in an error threshold level (also referred to as “ETL”) storage section 23, described later, with respect to data that is input from the host 3, and also has a selector 21B for assigning a parity to data to form encoded data. More specifically, the encoder 21 performs encoding processing of data stored in memory cells belonging to each block with an error correction number that is based on an error threshold level stored in the error threshold level storage section 23 and an error correction number correspondence table 25 that stores error threshold levels in correspondence with error correction numbers.

In order to detect and correct errors in encoded data that is read in page units from the memory section 30, the decoder 22 of the ECC 20 has a syndrome calculation section 22A that calculates a syndrome, an error position polynomial calculation section 22B that calculates an error position polynomial, a Chien search section 22C that searches for an error position, and an error correction section (unshown) that corrects an error at a specified error position.

More specifically, in decoding processing, first a syndrome is calculated at the syndrome calculation section 22A. When a syndrome calculation value is zero it means that a number of errors N is zero, and since it is not necessary to perform error correction, the data in question is output to the host 3 through the host interface 12. When the syndrome calculation value is not zero, an error position polynomial is calculated at the error position polynomial calculation section 22B based on the syndrome. When a coefficient of the error position polynomial that is calculated is expressed with an Nth order polynomial, it means that there are N errors.

When it is found that there are N errors by means of the error position polynomial calculation, as the next step an error position is specified at the Chien search section 22C. At the Chien search section 22C, all possible values (for example, 0 to M; where M is a final bit position or a final byte position) are sequentially assigned to a variable X of an Nth-order error position polynomial to search for whether or not the error position polynomial is satisfied. Subsequently, when all N solutions are specified, the error correction section corrects the error data en bloc.

In the case of encoded data that has BCH codes, error correction at the error correction section is performed by bit inversion. In the case of encoded data that has Reed-Solomon codes, a value after error correction is calculated as 8-bit data by further solving a simultaneous linear equation.

The function section 18 has an error threshold level storage section 23 that stores error threshold levels ETL in correspondence with error correction numbers that correspond to each block; an uncorrected number measurement section 26 that measures an uncorrected number of an error correction for each block at a time of decoding processing; an error threshold level modification section 24 that increases an ETL corresponding to each block stored in the error threshold level storage section 23 each time that the uncorrected number that is measured by the uncorrected number measurement section 26 exceeds a predetermined number; and an error correction number correspondence table 25 that stores a correspondence between an ETL and an error correction number T. More specifically, the memory controller 10 automatically adjusts an error correction number for each respective block.

Although the function section 18 is described here as an independent component to facilitate the description, each component of the function section 18 is a part of the CPU 11 and the RAM 15 that are described already. For example, operations of the uncorrected number measurement section 26 and the error threshold level modification section 24 are executed by the CPU 11 using firmware (FW). Further, the error threshold level storage section 23 and the error correction number correspondence table 25 are a part of the RAM 15. Naturally, each component of the function section 18 may also be a component that is actually independent from the CPU 11 or the RAM 15.

In this case, in the semiconductor memory apparatus 2 that has a NAND-type flash memory section, errors when reading stored data tend to increase accompanying an increase in the number of writes/erases. This is due to a high voltage being applied to a gate with respect to a board and electrons being injected into a floating gate in write/erase processing for a memory cell 31 of the NAND-type flash memory section. Since an oxide film around a floating gate deteriorates as the number of write/erase operations increases, the number of errors increases. Further, in the plurality of blocks within the memory section 30, a number of write/erase operations differs for each block.

To prevent uncorrected errors from arising even after long-term use, first, it is necessary to set an error correction number by taking into consideration, for example, a future increase in error occurrence at a time of factory shipment. Thus, as described previously, the efficiency of error correction processing deteriorates.

In contrast, the memory controller 10 performs decoding processing with a small error correction number when commencing use of the semiconductor memory apparatus 2, and increases an error correction number for each block in accordance with an increase in error occurrence.

In this connection, prior to commencing use of the semiconductor memory apparatus 2, the memory controller 10 may set an initial value of an error correction number for a block for which it is clear that the number of write/erase operations is large, for example, a block of an FAT area, to a value that is greater than that of other blocks.

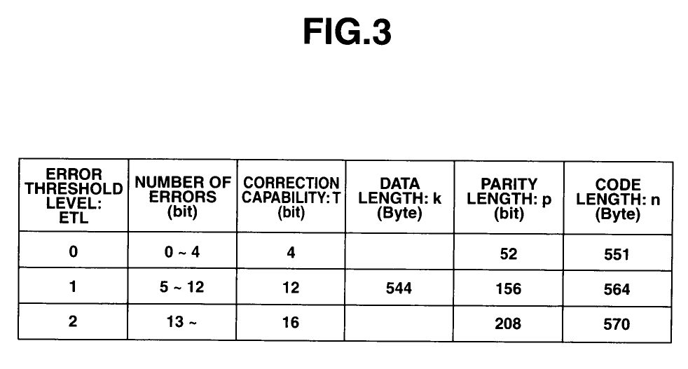

FIG. 3 is a view that shows an example of the error correction number correspondence table 25 of the memory controller 10 according to the present embodiment. In the example shown in FIG. 3, error correction numbers are classified into three levels, namely, error threshold levels 0, 1, and 2. Although a correction capability at the error threshold level 0 is small at four bits to correspond with errors of 0 to 4 bits, a parity length p thereof is also small at seven bytes. A correction capability at the error threshold level 1 is 12 bits, to correspond with errors of 5 to 12 bits, and a parity length p thereof is 20 bytes. Further, although a correction capability at the error threshold level 2 is large at 16 bits to correspond with errors of 13 to 16 bits, a parity length p thereof is long at 26 bytes. The above described error correction number correspondence table is an example when a maximum error correction number of the ECC 20 is 16 bits, and the error correction number correspondence table is appropriately set in accordance with the maximum error correction number of the ECC 20.

More specifically, the memory controller 10 classifies error correction numbers into error threshold levels ETL, and reduces the occurrence frequency of error correction number modification processing by using the error correction number correspondence table 25 that stores the correspondence between the ETLs and error correction numbers T. Consequently, the decoding processing efficiency at the memory controller 10 is favorable.

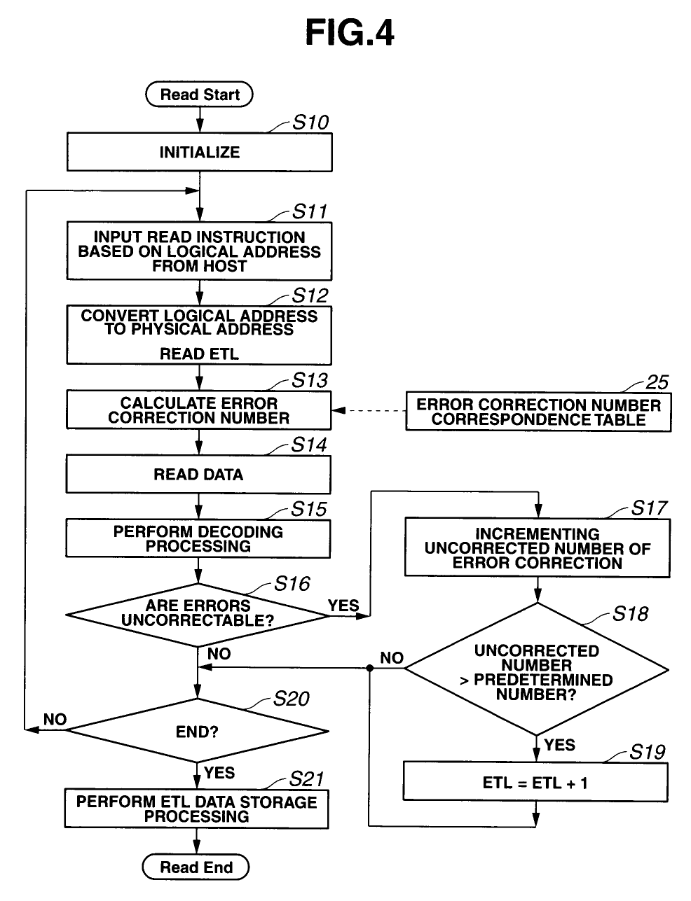

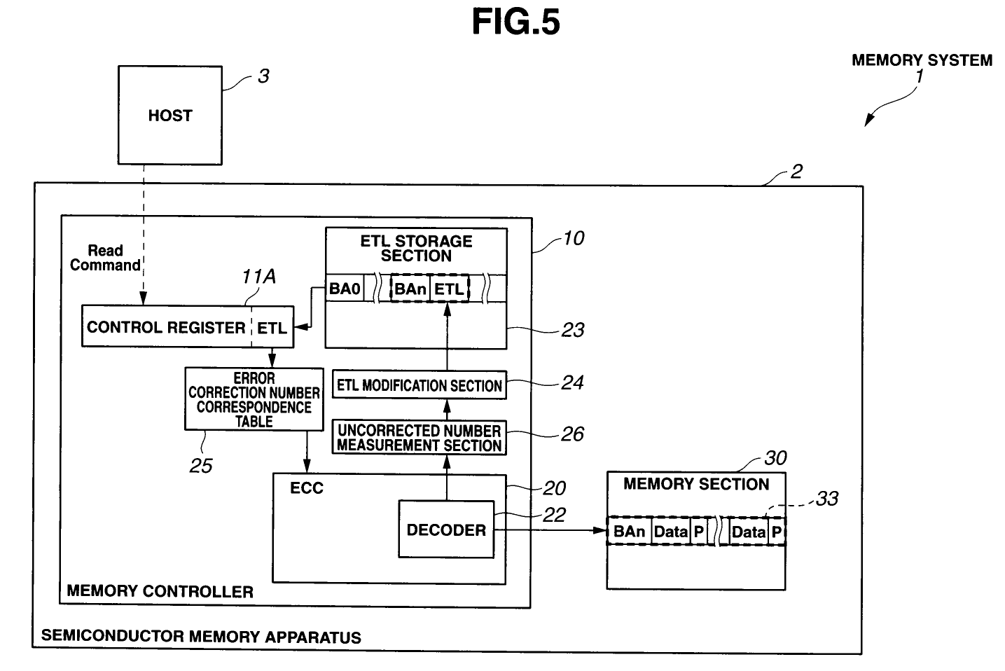

Next, the decoding processing of the memory controller 10 is described using FIG. 4 and FIG. 5. FIG. 4 is a flowchart for describing decoding processing of the memory controller 10. The decoding processing is described hereunder according to the flowchart shown in FIG. 4.

### <Step S10> Initialization Step

At a time of factory shipment of the semiconductor memory apparatus 2, the memory controller 10 stores error threshold levels ETL in accordance with blocks in the error correction number correspondence table 25.

Subsequently, after use of the semiconductor memory apparatus 2 commences, the memory controller 10 stores error threshold levels ETL that are in accordance with an uncorrected number for each block when use at a preceding time has ended, in the error correction number correspondence table 25.

More specifically, together with a logical address/physical address conversion table (not shown), for example, the memory controller 10 transfers the error correction number correspondence table 25, an uncorrected number that is measured by the uncorrected number measurement section 26 when use at a preceding time has ended, and information for error threshold levels of each block that are stored in the memory section 30 and the like to the RAM 15. Further, the CPU 11 transfers FW for performing operations of the uncorrected number measurement section 26 and the error threshold level modification section 24 from the ROM 13 or the like to the CPU 11.

In this connection, according to the memory controller 10 shown in FIG. 5, error threshold levels ETL up to the current time are stored in association with block addresses BA in the ETL storage section 23. More specifically, an error threshold level ETL is associated with a block address BA, and the ETL of the relevant block and a code length n are stored.

### <Step S11> Read Command Input

A read command for data for which a position is specified with a logical address from the host 3 is input. More specifically, according to the semiconductor memory apparatus 2, in order to avoid write/erase processing being concentrated in a specific memory cell, so-called “wear leveling” is implemented that counts a number of erasures and then substitutes a memory cell that has a high number of erasures with a memory cell that has a small number of erasures to average the number of write/erase operations among memory cells.

In the semiconductor memory apparatus 2 that performs wear leveling, it is difficult for a host to specify a data storage position using a physical address that indicates a physical position in a memory section of a memory cell. Therefore, a position of data is specified from the host 3 by a logical address that shows a position in a logical space.

### <Step S12> Logical to Physical Conversion; ETL Read

The memory controller 10 converts the logical address to a physical address using a logical address/physical address conversion table (not shown).

The memory controller 10 also, for example, reads into a control register 11A an error threshold level ETL of a block to which belongs the memory cell 31 at the physical address as the read-out target that is stored in the error threshold level storage section 23 as a subtable associated with the logical address/physical address conversion table. The control register 11A is, for example, a part of the CPU 11.

### <Step S13> Error Correction Number Calculation

The memory controller 10 calculates an error correction number corresponding to a block that is the read-out target based on the error correction number correspondence table 25 stored in the RAM 15 and an error threshold level corresponding to the block.

Although error correction numbers are classified into three levels in the error correction number correspondence table 25 shown in FIG. 3, the error correction numbers may be classified into more than three levels. For example, the error correction numbers may be classified into a number of levels that is the same as the error correction numbers.

### <Step S14> Data Read

The memory controller 10 reads encoded data of the memory cell 31 that is the read-out target.

### <Step S15> Decoding Processing

The decoder 22 of the memory controller 10 performs decoding processing of encoded data, and when it has been possible to perform the decoding, that is, when a number of errors is less than or equal to an error correction number, the data for which error correction has been performed is output to the host 3.

### <Step S16> Errors Uncorrected Judgment

When a number of errors exceeds an error correction number in encoding processing, the decoder 22 outputs an error uncorrected signal to the uncorrected number measurement section 26.

### <Step S17> Incrementing Uncorrected Number of Error Correction

Upon receiving the error uncorrected signal from the decoder 22, the uncorrected number measurement section 26 increments by one an internal uncorrected number counter (not shown) that corresponds to the block to which the memory cell in which the relevant data has been stored belongs.

### <Step S18> Comparison of Uncorrected Number of Error Correction

The uncorrected number measurement section 26 compares the count of the uncorrected number counter, that is, the uncorrected number, with an uncorrected number threshold value that is a predetermined number. The uncorrected number threshold value is previously set by the semiconductor memory apparatus 2. It is sufficient to set the uncorrected number threshold value to a value of 1 or more, and, for example, 100.

### <Step S19> Error Threshold Level Modification

When the uncorrected number exceeds the uncorrected number threshold value, the error threshold level modification section 24 increments by one the error threshold level of the relevant block to change the error threshold level of the block to a level with a higher error correction capability. At this time, the uncorrected number measurement section 26 resets the count of the uncorrected number counter.

In this connection, the uncorrected number threshold value may differ according to the error threshold level. For example, the uncorrected number threshold value may be 10 for a modification from error threshold level 0 to error threshold level 1, and may be 100 for a modification from error threshold level 1 to error threshold level 2.

### <Step S20> Continuation of Processing

The memory controller 10 repeats the above described processing until an end instruction is received from the host 3.

### <Step S21> ETL Data Storage Processing

When an end instruction is received from the host 3, the memory controller transfers a count of the uncorrected number counter of the uncorrected number measurement section 26 and information of the error threshold level storage section 23 to the memory section 30 or the like to be stored therein.

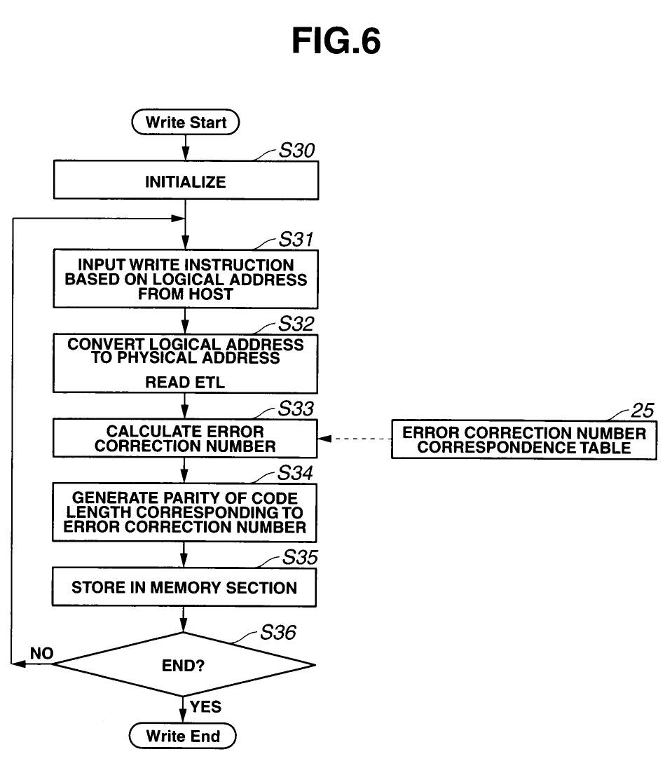

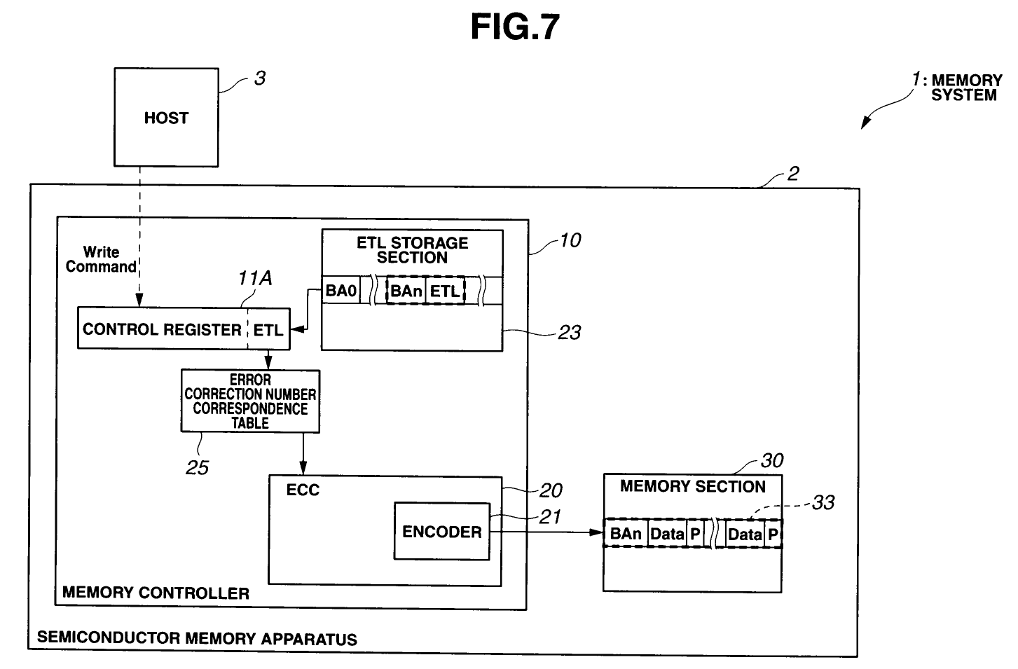

Next, encoding processing of the memory controller 10 is described using FIG. 6 and FIG. 7. FIG. 6 is a flowchart for describing encoding processing of the memory controller 10. The encoding processing is described hereunder according to the flowchart shown in FIG. 6.

### <Step S30> Initialization

The memory controller 10 transfers the error correction number correspondence table 25 and the like stored in the memory section 30 and the like to the RAM 15 or the like.

### <Step S31> Write Command Input

A write command for data for which a position is specified with a logical address is input from the host 3.

### <Step S32> Logical to Physical Conversion; ETL Read

The memory controller 10 converts the logical address to a physical address using a logical address/physical address conversion table (not shown).

Further, the memory controller 10 reads into the control register 11A an error threshold level ETL of a block to which belongs a memory cell 31 at the physical address obtained as the result of the conversion, that is stored in the error threshold level storage section 23.

### <Step S33> Error Correction Number Calculation

The memory controller 10 calculates an error correction number corresponding to the target block based on the error correction number correspondence table 25 and an error threshold level corresponding to the block.

### <Step S34> Parity Generation

The encoder 21 generates a parity of a code length in accordance with the error correction number, and adds the parity to the data to generate encoded data.

### <Step S35> Storage Processing

The memory controller 10 stores the encoded data in the memory cell 31 inside the specified block of the memory section 30.

### <Step S36> Continuation of Processing

The memory controller 10 repeats the above described processing until an end instruction is received from the host 3.

As described above, since the memory controller 10 of the present embodiment makes an error correction number for an initial setting at a time of factory shipment smaller than a maximum error correction number of the ECC section 20, a parity length is short and a capacity of the memory section 30 that can be used by a user is large. Further, because the memory controller 10 and the semiconductor memory apparatus 2 create encoded data with a small error correction number, processing loads of the encoder 21 and the decoder 22 are small, processing speeds are fast, and power consumption is low. Hence the error correction processing efficiency is favorable.

In addition, according to the memory controller 10 and the semiconductor memory apparatus 2, even when data errors of any one block increase accompanying use of the semiconductor memory apparatus 2, it is possible to perform automatic adjustment in block units to an optimal value in accordance with an increase in an error occurrence rate in block units, and hence the error correction processing efficiency is favorable. More specifically, the memory controller 10 and the semiconductor memory apparatus 2 can automatically adjust an error correction number to an optimal value flexibly in accordance with a number of errors and an error level, in other words, in accordance with the reliability of the memory section 30.

In this connection, although in the above description an example is described in which a block is taken as a set unit, a configuration may also be adopted which takes a block group including a plurality of blocks as a set unit.

### Second Embodiment

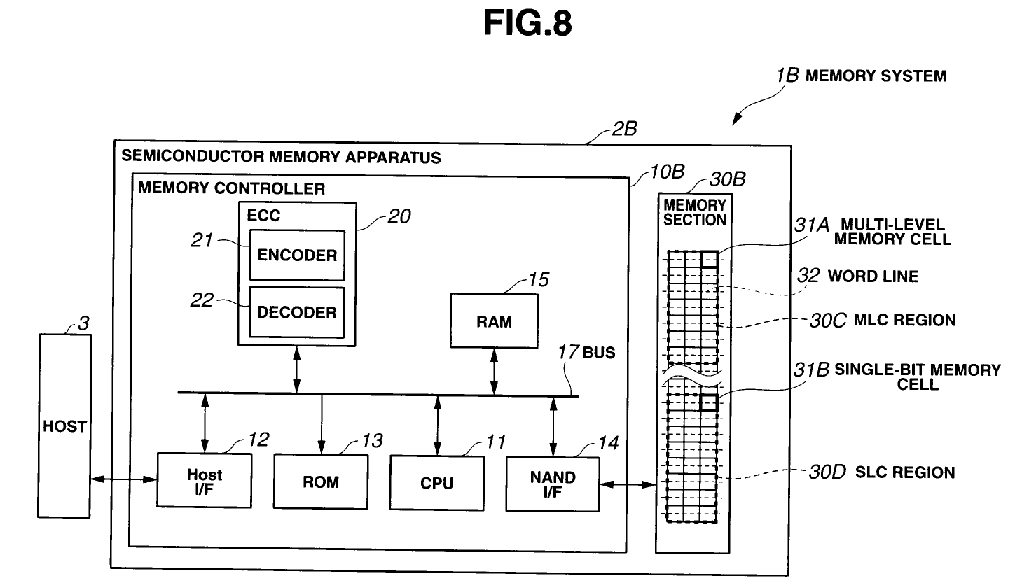

Hereunder, a memory controller 10B and a semiconductor memory apparatus 2B of a second embodiment of the present invention are described with reference to FIG. 8. Since a memory system 1B, the memory controller 10B, and the semiconductor memory apparatus 2B of the second embodiment resemble the memory system 1, the memory controller 10, and the semiconductor memory apparatus 2 of the first embodiment, hereunder the same components are denoted by the same reference numbers and a description of those components is omitted.

A memory section 30B of the semiconductor memory apparatus 2B includes a multi-level cell (MLC) region 30C that includes a so-called multi-level memory cell 31A for which a number of data bits stored in a single memory cell 31 is two, and a single-level cell (SLC) region 30D that includes a single-bit memory cell 31B for which a number of data bits stored in a single memory cell 31 is one. Because the multi-level memory cell 31A is capable of storing twice the amount of data as the single-bit memory cell 31B, the multi-level memory cell 31A contributes significantly to providing the semiconductor memory apparatus 2B with a large capacity. However, in comparison to the single-bit memory cell 31B, errors are more liable to occur at the time of a read operation with respect to the multi-level memory cell 31A.

The memory controller 10B of the semiconductor memory apparatus 2B changes an error correction number at a time of encoding processing with respect to a set unit of memory cells having multi-level memory cells 31A, and a set unit of memory cells having single-bit memory cells 31B.

More specifically, the memory controller 10B of the semiconductor memory apparatus 2B manages an error correction number for each set unit that is composed of memory cells that have the same number of data bits stored in a single memory cell. For example, in the memory controller 10B of the semiconductor memory apparatus 2B that has two-bit memory cells for which the number of data bits stored in a single memory cell is two, and three-bit memory cells for which the number of data bits stored in a single memory cell is three, the two-bit memory cells and the three-bit memory cells are taken as set units.

In the memory controller 10B and the semiconductor memory apparatus 2B of the present embodiment, even when a degree of error occurrence differs depending on a set unit of memory cells because the numbers of bits stored in the memory cells are different, similarly to the first embodiment the error correction processing efficiency is favorable.

### Modification Example of Second Embodiment

According to the memory controller 10B and the semiconductor memory apparatus 2B of the second embodiment, an error correction number at a time of encoding processing is set for a set unit of memory cells including multi-level memory cells 31A and for a set unit of memory cells including single-bit memory cells 31B. However, a set unit of memory cells is not limited to these set units.

For example, in a case in which the memory section 30 physically has a plurality of regions, i.e., plains, a plain may be taken as a set unit. Further, a page that is a data read unit may be taken as a set unit. When taking a page as a set unit, an uncorrected number and an error threshold level of the page can be stored in a management section (redundancy section) of the page.

In addition, since there are cases in which an error occurrence rate increases physically in a specific word line or column region even within the same block, a word line unit or a column region may be taken as a set unit. More specifically, as set units, odd number and even number page units at the word line 32, and an ECC frame unit specifically for a head/end column inside a page and the like may be mentioned. In other words, a set unit of memory cells is composed of a plurality of memory cells that are classifiable by a reliability parameter that depends on a physical structure within a memory section.

Further, similarly to a block group, a group composed of a plurality of the set units may be taken as a unit. Furthermore, a unit may be formed by combining different kinds of set unit, such as a combination of a block and a word line.

Having described the preferred embodiments of the invention referring to the accompanying drawings, it should be understood that the present invention is not limited to those precise embodiments and various changes and modifications thereof could be made by one skilled in the art without departing from the spirit or scope of the invention as defined in the appended claims.

What is claimed is:

1. A memory controller configured to control an error correction for a flash memory section, comprising:
an error correction number correspondence table that stores an error threshold level in correspondence with an error correction number when performing encoding processing of data stored in the flash memory section, the error correction number capable of being increased or decreased, and the flash memory section being composed of a plurality of memory cells that are each classifiable into any one of a plurality of set units;
an error threshold level storage section that stores an error threshold level for each of the set units;
an uncorrected number measurement section that measures an uncorrected number of an error correction for each of the set units;
an error threshold level modification section that, each time the uncorrected number of a certain set unit exceeds a predetermined number, modifies the error threshold level of the relevant set unit that is stored in the error threshold level storage section to a new error threshold level;
an encoder that performs the encoding processing with the error correction number that is based on the error threshold level stored in the error threshold level storage section and the error correction number correspondence table; and
a decoder that performs decoding processing of data that is stored in the flash memory section.

2. The memory controller according to claim 1,
wherein the set unit is comprised by a plurality of memory cells that are classifiable by a reliability parameter that depends on a physical structure of the flash memory section.

3. The memory controller according to claim 1,
wherein the set unit is a block that is an erase unit.

4. The memory controller according to claim 1,
wherein the set unit is a plurality of the blocks.

5. The memory controller according to claim 1,
wherein the set unit is a set unit that comprises the memory cells in which a number of data bits stored in each of the memory cells is the same.

6. The memory controller according to claim 1,
wherein the set unit is a page that is a data read unit.

7. The memory controller according to claim 1,
wherein an initial value of the error threshold level is set for each of the set units.

8. The memory controller according to claim 1,
wherein the predetermined number at which the error threshold level modification section modifies an error threshold level of the set unit differs according to the error threshold level.

9. A semiconductor memory apparatus, comprising:
a flash memory section composed of a plurality of memory cells that are each classifiable into any one of a plurality of set units;
an error correction number correspondence table that stores an error threshold level in correspondence with an error correction number of a memory controller when performing encoding processing of data stored in the flash memory section, the error correction number capable of being increased or decreased;
an error threshold level storage section that stores an error threshold level for each of the set units;
an uncorrected number measurement section that measures an uncorrected number of an error correction for each of the set units;
an error threshold level modification section that, each time the uncorrected number of a certain set unit exceeds a predetermined number, modifies the error threshold level of the relevant set unit that is stored in the error threshold level storage section to a new error threshold level;
an encoder that performs the encoding processing with the error correction number that is based on the error threshold level stored in the error threshold level storage section and the error correction number correspondence table; and
a decoder that performs decoding processing of data that is stored in the flash memory section.

10. The semiconductor memory apparatus according to claim 9,
wherein the set unit is comprised by a plurality of memory cells that are classifiable by a reliability parameter that depends on a physical structure of the flash memory section.

11. The semiconductor memory apparatus according to claim 9,
wherein the set unit is a block that is an erase unit.

12. The semiconductor memory apparatus according to claim 9,
wherein the set unit is a plurality of the blocks.

13. The semiconductor memory apparatus according to claim 9,
wherein the set unit is a set unit that comprises the memory cells in which a number of data bits stored in each of the memory cells is the same.

14. The semiconductor memory apparatus according to claim 9,
wherein the set unit is a page that is a data read unit.

15. The semiconductor memory apparatus according to claim 9,
wherein an initial value of the error threshold level is set for each of the set units.

16. The semiconductor memory apparatus according to claim 9,
wherein the predetermined number at which the error threshold level modification section modifies an error threshold level of the set unit differs according to the error threshold level.

17. A semiconductor memory apparatus, comprising:
a NAND-type flash memory section composed of a plurality of memory cells classifiable into any block that is an erase unit;
an error correction number correspondence table that stores an error threshold level in correspondence with an error correction number of a memory controller when performing encoding processing of data stored in the flash memory section, the error correction number capable of being increased or decreased by the block;
an error threshold level storage section that stores an error threshold level for each of the blocks;
an uncorrected number measurement section that measures an uncorrected number of an error correction for each of the blocks;
an error threshold level modification section that, each time the uncorrected number of a certain block exceeds a predetermined number, modifies an error threshold level of the block that is stored in the error threshold level storage section to a new error threshold level;
an encoder that performs the encoding processing with the error correction number that is based on the error threshold level stored in the error threshold level storage section and the error correction number correspondence table; and
a decoder that performs decoding processing of data that is stored in the flash memory section.
